(19) United States
(12) Patent Application Publication
(10) Pub. No.: US 2026/0123284 A1
(43) Pub. Date: Apr. 30, 2026

(54) HEAT POWERED SENSOR

(71) Applicant: Microchip Technology Incorporated, Chandler, AZ (US)

(72) Inventors: Arthur B. Eck, Gilbert, AZ (US); Patrick McFarland, Gilbert, AZ (US)

(73) Assignee: Microchip Technology Incorporated, Chandler, AZ (US)

(21) Appl. No.: 19/068,265

(22) Filed: Mar. 3, 2025

Related U.S. Application Data
(60) Provisional application No. 63/712,555, filed on Oct. 28, 2024.

(51) Int. Cl. H10N 19/00; G08B 3/10; G08B 5/22; G08B 29/14

(52) U.S. Cl. CPC H10N 19/00; G08B 29/14; G08B 3/10; G08B 5/22

(57) ABSTRACT

Various embodiments of the teachings herein include a system comprising: a thermoelectric generator to convert heat into electrical power; and an output device. The electrical power from the thermoelectric generator powers the output device.

### RELATED APPLICATIONS

This application claims priority to U.S. Provisional Patent Application No. 63/712,555 filed Oct. 28, 2024, the contents of which are hereby incorporated in their entirety.

### TECHNICAL FIELD

The present disclosure relates to sensors. Various examples of the teachings herein include systems and/or methods for providing power to monitoring systems.

### BACKGROUND

In typical electronic devices, including monitors and sensors, various elements of the devices require electrical power. Typical elements of a monitoring system include, but are not limited to, sensor elements, transmitters, and processors. Wiring power and/or communications to a monitoring system increases the installation cost. Using batteries to provide power in a monitoring system increases the need for maintenance to replace the batteries. In addition, batteries may be physically compromised by surrounding conditions for some monitoring systems.

For the purposes of this disclosure, a monitoring system refers to an electronic device which monitors one or more conditions, such as a smoke detector or a thermostat. A sensor or sensor element refers to a specific element within such a monitoring system to detect a particular parameter or condition.

### SUMMARY

As an example, some embodiments of the teachings of the present disclosure include a system comprising: a thermoelectric generator to convert heat into electrical power; and an output device; wherein electrical power from the thermoelectric generator powers the output device.

As another example, some embodiments of the teachings herein include a method for operating a monitoring system, the method comprising: converting heat into electrical power using a thermoelectric generator; and providing the electrical power to an output device of the monitoring system.

### BRIEF DESCRIPTION OF THE DRAWINGS

FIG. 1 illustrates a portion of an example system incorporating teachings of the present disclosure;

FIG. 2 illustrates the example system of FIG. 1 in an exploded view;

FIG. 3 illustrates an example system incorporating teachings of the present disclosure;

FIG. 4 illustrates an example system incorporating teachings of the present disclosure; and

FIG. 5 illustrates an example system incorporating teachings of the present disclosure.

### DETAILED DESCRIPTION

The teachings of the present disclosure may use heat in the surroundings of the monitoring system to provide power to elements thereof. For example, some monitoring systems are configured to sense conditions that include raised temperature, such as a smoke or fire detector. Examples of the teachings herein may include monitoring systems that convert heat in the surroundings to power for sensor elements, transmitters, and/or other components of the monitoring system.

For example, some monitoring systems incorporating teachings of the present disclosure may include a thermoelectric generator. A thermoelectric generator typically comprises a solid-state device converting heat into electrical energy. Some examples of a thermoelectric generator include a thermocouple, a thermopile, a Seebeck generator, and a Sterling engine. In a monitoring system, the output of a thermoelectric generator may be used indicate heat and/or the absence of heat. Further, resulting electrical power may be used to power sensor elements, transmitters, or other components of the monitoring system.

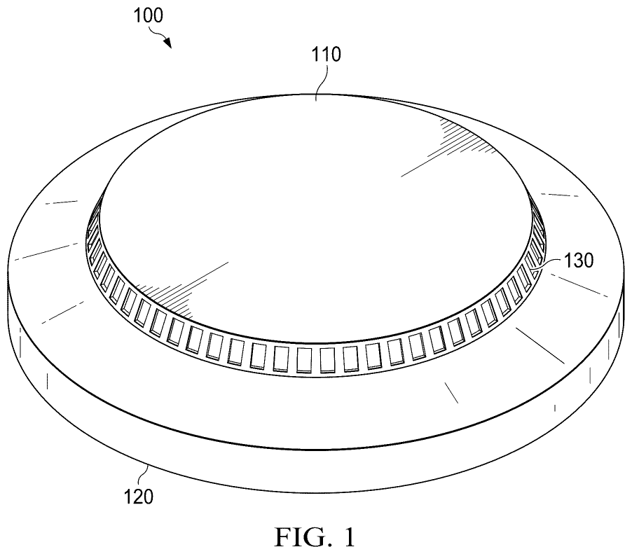

FIG. 1 illustrates an example monitoring system 100 incorporating teachings of the present disclosure. Monitoring system 100 may include a housing 110, a base 120, and a plurality of passageways 130. Although FIG. 1 shows a housing with a plurality of passageways 130 allowing air flow into and out of the housing 110, other monitoring systems.

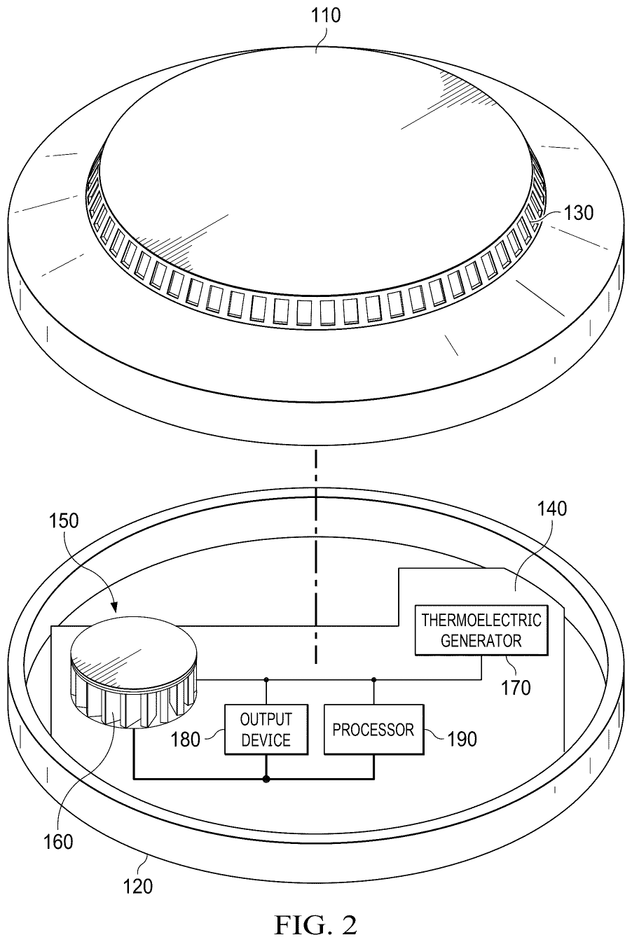

FIG. 2 illustrates the example monitoring system 100 in an exploded view. As shown in FIG. 2, the monitoring system 100 includes a printed circuit board 140, an internal housing 150, one or more sensor elements 160, a thermoelectric generator 170, an output device 180, and a processor 190.

The external housing top 110 and the external housing base 120 may be separate parts defining an interior. As shown, the monitoring system 100 includes a printed circuit board (PCB) 140. PCB 140 provides a mounting surface for an internal housing 150 which may define a test chamber. PCB 140 may include circuitry or leads to provide power and/or signals to components of the internal housing 150. As an example, a processor may be mounted to the PCB 140 and connected to the internal housing 150 by printed circuits or conductive tracks on the PCB 140. In some systems, there may be a mounting surface that is not a PCB. For example, the internal housing 150 may be mounted directly to either the external housing top 110 or the external housing base 120. As another example, the internal housing 150 may be mounted to different elements of the system.

The internal housing 150 houses one or more sensor elements 160. As shown, the one or more sensor elements are within the internal housing 150, but the one or more sensor elements 160 may be mounted directly to the PCB 140 or to either portion of the housing 110. The one or more sensor elements 160 may monitor any appropriate parameter and may operate under any appropriate scheme, including without limitation by generating and/or measuring a capacitance, a current, a resistance, etc. As shown, the one or more sensor elements 160 are exposed to any air flow within the housing 110 and/or within the internal housing 150.

The one or more sensor elements 160 may comprise any appropriate sensor element. Some examples include, but are not limited to: a thermometer, a strain gauge, a particulate matter sensor, and a gas sensor.

The thermoelectric generator 170 operates to convert heat into electrical power. The output of the thermoelectric generator 170 may indicate heat and/or the absence of heat. Further, the generated electrical power may be used to power the one or more sensor elements 160, transmitters, or other components of the monitoring system. The thermoelectric generator 170 may comprise a solid-state device. Some examples of include a thermocouple, a thermopile, a Seebeck generator, and a Sterling engine.

Using thermoelectric generator 170 to power other elements of the monitoring system 100 may reduce total installation and/or operating costs of the monitoring system 100. The teachings herein may allow installation without wiring connections to power or a communications network. Further, the teachings herein may allow deployment without batteries. In some cases, the monitoring system 100 may be exposed to heat levels sufficient generate electrical power with the thermoelectric generator 170 under normal operating conditions. In those cases, the loss of heat causes the thermoelectric generator 170 to stop generating electrical power. In some cases, the monitoring system 100 may be expected to operate in a low temperature environment (under HVAC, cryogenic, etc.). In those cases, an increase in temperature may indicate a loss of environmental system operation and the effect on the thermoelectric generator 170 may provide a signal or alert of that loss by either interrupting or increasing the electrical power.

In some monitoring systems 100, a transmitter or other output device 180 emits an operational signal. The loss of electrical power to the output device 180 will result in a loss of the operational signal. The loss of the operational signal may be used to trigger an alarm, an alert, or some other corrective action in such monitoring systems.

The output device 180 may include any element operable to generate an output. The output device 180 may generate an audible noise, a visible signal, a wireless signal, or an electronic or other type of communication. For example, some monitoring systems 100 include sensor elements for parameters related to strain, presence of particulate matter, and/or presence of a gas. If the sensor elements 160 detect the parameter, output device 180 may generate the output corresponding to the parameter. In some examples, the output device 180 may be triggered in response to receiving electrical power from the thermoelectric generator 170. In such instances, the monitoring system 100 may be used to monitor heat and operate without additional sensor elements 160. Some monitoring systems 100 may include an output device 180 including a transmitter powered when a particular condition is sensed. The transmitter may be used to communicate a sensed condition, an identifier for the monitoring system 100, and/or additional data.

In some examples, such as that shown in FIG. 2, the monitoring system 100 may include a processor 190. The processor 190 may monitor output from the one or more sensor elements 160 to compare the output with a criterion. If the criterion is met, the processor 190 may trigger the output device 180. In some examples, if the monitoring system is exposed to enough heat, the thermoelectric generator 170 may provide electrical power to the processor 190 and, in turn, the processor 190 may compare the output of the thermoelectric generator 170 as an indicator of heat present in the surroundings of the monitoring system 100 and may compare the heat level against a predetermined threshold. In some examples, the thermoelectric generator 170 may not be encased but rather directly exposed to any surrounding atmosphere of the monitoring system 100.

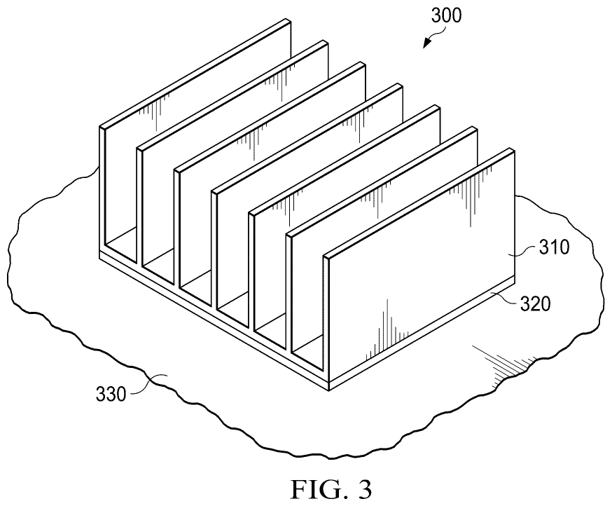

FIG. 3 illustrates an example system incorporating teachings of the present disclosure. As shown in FIG. 3, the system 300 includes a heat sink with fins 310, a thermoelectric generator 320, and a heat source 330. In this case, the heat source 330 generates heat which travels through the thermoelectric generator 320 to the heat sink 310, dissipating heat to the surrounding area or atmosphere. In some cases, the heat source 330 may be replaced by a cold source (or a heat sink). In that instance, heat may be collected by the heat sink 310 and transferred through the thermoelectric generator 320 to the cold source. The change in temperature across the thermoelectric generator 320 creates a difference in electric potential, as discussed herein. The thermoelectric generator 320 and the heat sink 310 may be exposed directly to the surroundings.

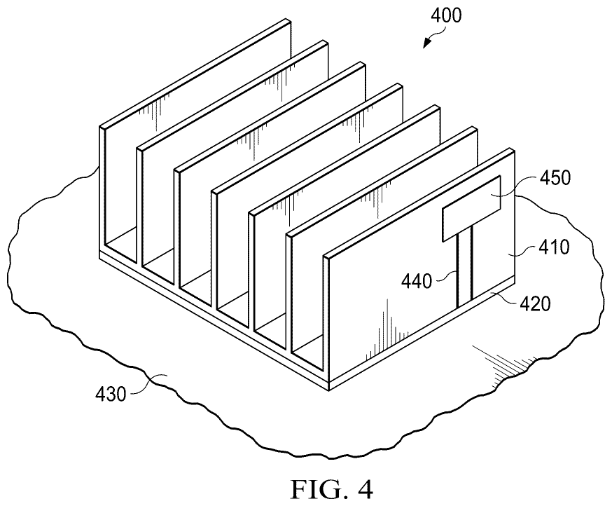

FIG. 4 illustrates an example system 400 incorporating teachings of the present disclosure. System 400 includes a heat sink with fins 410, a thermoelectric generator 420, a heat source 430, power lines 440, and a circuit 450. In this case, heat from the heat source 430 travels through the thermoelectric generator 420 to the heat sink 410, dissipating heat to the surrounding area or atmosphere through the increased surface area provided by the fins. In operation, the thermoelectric generator 420 provides power through power lines 440 to the circuit 450. The circuit 450 uses the power to transmit data by any appropriate protocol. While the heat sink 410 and the thermoelectric generator 420 may be exposed directly to a surrounding atmosphere, the circuit 450 may be encapsulated or otherwise encased to protect the circuit 450 from the atmosphere.

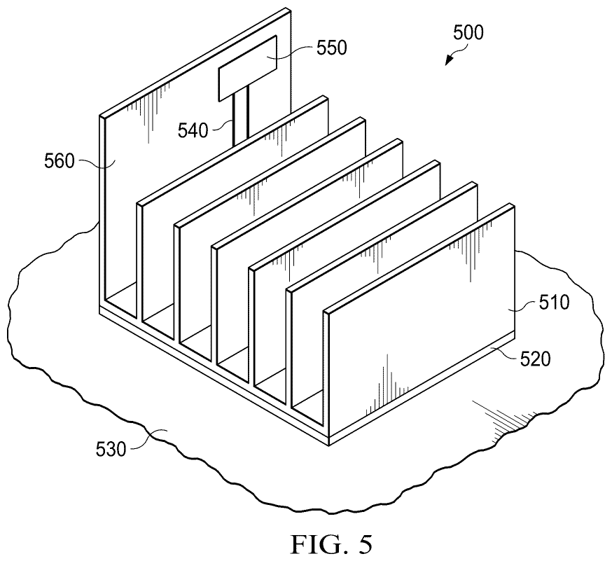

FIG. 5 illustrates an example system 500 incorporating teachings of the present disclosure. System 500 includes a heat sink 510, a thermoelectric generator 520, a heat source 530, power lines 540, and a circuit 550. In this case, heat from the heat source 530 travels through the thermoelectric generator 520 to the heat sink 510, dissipating heat to the surrounding area or atmosphere through the increased surface area provided by the fins. In operation, the thermoelectric generator 520 provides power through power lines 540 to the circuit 550. The circuit 550 uses the power to transmit data by any appropriate protocol. As shown in FIG. 5, the circuit 550 may be mounted to an extended fin 560 of the heat sink 510. In this case, the extended fin 560 may provide increased thermal isolation to the circuit 550. In some cases, the circuit 550 may be mounted to a fin or another part of heat sink 510 which is thermally insulated and/or isolated from the heat source 530. In some cases, the extended fin 560 or another fin or extension of the heat sink 510 may operate as an antenna for transmissions to or from the circuit 550.

The teachings of the present disclosure allow installation and use of monitoring systems with no energy storage devices such as electric batteries. Further, the teachings allow installation of monitoring systems which require no wired connections to an exterior network for power or communication.

We claim:

1. A system comprising:
an attachable thermoelectric generator to convert heat into electrical power; and
an output device;
wherein electrical power from the thermoelectric generator powers the output device.

2. The system as recited in claim 1, wherein the output device includes a transmitter.

3. The system as recited in claim 1, wherein the output device includes an audible or visible alarm.

4. The system as recited in claim 1, further comprising one or more sensor elements;
wherein the electrical power powers the one or more sensor elements.

5. The system as recited in claim 1, further comprising:
one or more sensor elements; and
a processor;
wherein the electrical power powers the one or more sensor elements and the processor; and
the processor monitors output from the one or more sensor elements and, in response to a predetermined criterion sensed by the one or more sensor elements, triggers the output device.

6. The system of claim 1, wherein the thermoelectric generator comprises a thermopile.

7. The system of claim 1, wherein further comprising one or more sensor elements;
wherein the electrical power powers the one or more sensor elements; and
the one or more sensor elements comprise at least one element selected from the group consisting of: a thermometer, a strain gauge, a particulate matter sensor, and a gas sensor.

8. The system of claim 1, further comprising no energy storage devices.

9. The system of claim 1, further comprising:
a housing; and
no wiring for power or communication extending beyond the housing.

10. A method for operating a monitoring system, the method comprising:
converting heat into electrical power using an attachable thermoelectric generator; and
providing the electrical power to an output device of the monitoring system.

11. The method as recited in claim 10, further comprising:
providing the electrical power to one or more sensor elements; and
monitoring an alarm criterion with the one or more sensor elements.

12. The method as recited in claim 10, wherein the output device includes a transmitter.

13. The method as recited in claim 10, wherein the output device includes an audible or visible alarm.

14. The method as recited in claim 10, further comprising:
providing the electrical power to one or more sensor elements and a processor;
using the processor to monitor output from the one or more sensor elements and, in response to a predetermined criterion sensed by the one or more sensor elements, trigger the output device.

15. The method as recited in claim 10, wherein the thermoelectric generator comprises a thermopile.

16. The method as recited in claim 10, further comprising providing the electrical power to one or more sensor elements;
wherein the one or more sensor elements comprise at least one element selected from the group consisting of: a thermometer, a strain gauge, a particulate matter sensor, and a gas sensor.

17. The method as recited in claim 10, wherein the monitoring system comprises no energy storage devices.

18. The method as recited in claim 10, wherein the monitoring system comprises a housing and no wiring for power or communication extending beyond the housing.
